(19) United States
(12) Patent Application Publication
(10) Pub. No.: US 2020/0373431 A1
(43) Pub. Date: Nov. 26, 2020

(54) THIN FILM TRANSISTOR, METHOD FOR MANUFACTURING SAME, AND DISPLAY APPARATUS

(71) Applicant: SAKAI DISPLAY PRODUCTS CORPORATION, Osaka (JP)

(72) Inventor: HIROYUKI OHTA, Osaka (JP)

(21) Appl. No.: 16/825,983

(22) Filed: Mar. 20, 2020

Related U.S. Application Data
(60) Provisional application No. 62/852,765, filed on May 24, 2019.

(51) Int. Cl. H01L 29/786; H01L 29/66; H01L 29/24; H01L 27/15; H01L 27/32; H01L 27/12

(52) U.S. Cl. CPC H01L 29/7869; H01L 29/66969; H01L 27/1225; H01L 27/15; H01L 27/3244; H01L 29/24

(57) ABSTRACT

A thin film transistor includes: an oxide semiconductor layer including a first region, a second region, and a channel region; a gate electrode provided on the channel region so as to overlap the channel region with a gate insulating layer interposed therebetween, the gate electrode overlapping the channel region but overlapping none of the first region and the second region; a source electrode electrically coupled with the first region; and a drain electrode electrically coupled with the second region. The channel region of the oxide semiconductor layer has a greater thickness than the first region and the second region, and the oxide semiconductor layer includes a lower layer and an upper layer provided on part of the lower layer. The channel region includes the upper layer and the lower layer, and each of the first region and the second region includes the lower layer but does not include the upper layer.

### BACKGROUND

### 1. Technical Field

The present invention relates to a thin film transistor and a method for manufacturing the same, and a display apparatus.

### 2. Description of the Related Art

Active matrix substrates are used in, for example, display apparatuses such as liquid crystal display apparatuses, organic EL (Electro Luminescence) display apparatuses, and micro LED (Light Emitting Diode) display apparatuses. The micro LED display apparatuses include a plurality of light-emitting diodes (LED) which are made of inorganic compounds and which are two-dimensionally arrayed.

In each pixel of an active matrix substrate, a circuit (which is referred to as “pixel circuit”) is provided which includes a thin film transistor (hereinafter, “TFT”). In some active matrix substrates, a peripheral circuit such as a driving circuit is monolithically provided. TFTs can also be used as circuit elements in the peripheral circuit.

In this specification, TFTs used in the pixel circuit are referred to as “pixel circuit TFTs”, and TFTs which are constituents of the peripheral circuit are referred to as “peripheral circuit TFTs”.

TFTs widely used in active matrix substrates are, traditionally, amorphous silicon TFTs in which an amorphous silicon film (hereinafter, referred to as “a-Si film”) is used as the active layer and polycrystalline silicon TFTs in which a polycrystalline silicon (polysilicon) film (hereinafter, referred to as “poly-Si film”) is used as the active layer. Instead of these silicon TFTs, TFTs which include an oxide semiconductor such as In—Ga—Zn—O based semiconductor (hereinafter, referred to as “oxide semiconductor TFTs”) are sometimes used.

For example, Japanese Laid-Open Patent Publication No. 2015-056566 and Japanese Laid-Open Patent Publication No. 2011-187506 disclose using oxide semiconductor TFTs which have a top gate configuration as the pixel circuit TFTs.

### SUMMARY

In current-driven display apparatuses such as micro LED display apparatuses and organic EL display apparatus, for example, light emitting devices (LEDs, organic EL devices, etc.) whose emission luminance varies according to the current are provided so as to correspond to respective pixels. The electric current supplied to the light emitting device of each pixel is controlled by a pixel circuit. Therefore, to achieve high luminance, using TFTs which have high channel mobility (current drivability) as the pixel circuit TFTs is preferred. In this specification, the mobility of a portion of the oxide semiconductor layer of a TFT which is to be the channel is referred to as “channel mobility” for the purpose of distinguishing from the mobility of the oxide semiconductor layer material itself (physical property).

Also in voltage-driven display apparatuses such as liquid crystal display apparatuses, for example, TFTs which are constituents of the peripheral circuit are required to have high channel mobility.

However, in conventional oxide semiconductor TFTs, there is a probability that sufficient channel mobility will not be achieved due to the physical properties of the oxide semiconductor. Particularly, in an oxide semiconductor TFT which has a top gate configuration, if the overlap length of the gate and the source/drain is decreased for the purpose of reducing the parasitic capacitance, the channel mobility further decreases.

One embodiment of the present invention was conceived in view of the foregoing circumstances. An object of the present invention is to provide an oxide semiconductor TFT which is capable of improving the channel mobility and a manufacturing method thereof, and a display apparatus which includes the oxide semiconductor TFT.

This specification discloses a thin film transistor, a display apparatus, and a manufacturing method of a thin film transistor, which are described in the following paragraphs.

[Item 1]

A thin film transistor including:

a substrate;

an oxide semiconductor layer supported by the substrate, the oxide semiconductor layer including a first region, a second region, and a channel region located between the first region and the second region;

a gate electrode provided on the channel region of the oxide semiconductor layer so as to overlap the channel region with a gate insulating layer interposed therebetween, the gate electrode overlapping the channel region of the oxide semiconductor layer but overlapping none of the first region and the second region when viewed in a normal direction of the substrate;

a source electrode electrically coupled with the first region of the oxide semiconductor layer; and

a drain electrode electrically coupled with the second region of the oxide semiconductor layer,

wherein the channel region of the oxide semiconductor layer has a greater thickness than the first region and the second region,

the oxide semiconductor layer includes a lower layer and an upper layer provided on part of the lower layer, and

the channel region includes the upper layer and the lower layer, and each of the first region and the second region includes the lower layer but does not include the upper layer.

[Item 2]

The thin film transistor of Item 1, wherein a thickness of the first region and the second region is not less than ¼ and not more than ½ of a thickness of the channel region.

[Item 3]

The thin film transistor of Item 1 or 2, wherein the oxide semiconductor layer includes a low-resistance region at an upper surface of the first region and the second region, the low-resistance region having lower specific resistance than the channel region.

[Item 4]

The thin film transistor of Item 3, wherein the low-resistance region is also provided at a lateral surface of the upper layer of the oxide semiconductor layer.

[Item 5]

The thin film transistor of Item 4, wherein

the low-resistance region contains a first metal element while the channel region does not contain the first metal element or contains the first metal element at a lower density than in the low-resistance region, and

an insulative film is provided on the low-resistance region so as to be in contact with the low-resistance region, the insulative film containing an oxide of the first metal element.

[Item 6]

The thin film transistor of Item 5, wherein the first metal element is Al, and the insulative film is an alumina film.

[Item 7]

The thin film transistor of any of Items 1 to 6, further including an upper insulating layer covering the oxide semiconductor layer, the gate insulating layer and the gate electrode, wherein

the source electrode is electrically coupled with the first region in a first opening provided in the upper insulating layer, and

the drain electrode is electrically coupled with the second region in a second opening provided in the upper insulating layer.

[Item 8]

The thin film transistor of any of Items 1 to 7, wherein a lateral surface of the gate electrode, a lateral surface of the gate insulating layer, and at least part of a lateral surface of the oxide semiconductor layer are aligned with one another.

[Item 9]

The thin film transistor of any of Items 1 to 8, wherein

the gate insulating layer includes a silicon oxide layer, and

the silicon oxide layer contains a second metal element, and the second metal element is Mg or La.

[Item 10]

The thin film transistor of Item 9, wherein the gate electrode includes a first metal layer which contains the second metal element, and the first metal layer is in contact with an upper surface of the silicon oxide layer.

[Item 11]

The thin film transistor of Item 10, wherein the gate electrode includes the first metal layer and a second metal layer provided on the first metal layer.

[Item 12]

The thin film transistor of any of Items 1 to 11, wherein the oxide semiconductor layer contains In, Ga and Zn.

[Item 13]

A display apparatus including:

the thin film transistor as set forth in any of Items 1 to 12;

a display region which has a plurality of pixels; and

a pixel circuit arranged so as to correspond to respective ones of the plurality of pixels,

wherein the pixel circuit includes the thin film transistor.

[Item 14]

The display apparatus of Item 13, further including a current-driven light emitting device arranged so as to correspond to respective one of the plurality of pixels, wherein the pixel circuit drives the light emitting device.

[Item 15]

A manufacturing method of a thin film transistor supported by a substrate, the method including:

(A) forming an oxide semiconductor film on the substrate;

(B) forming a gate insulative film and an electrically-conductive gate film in this order on the oxide semiconductor film;

(C) patterning the electrically-conductive gate film using a first mask, thereby forming a gate electrode so as to overlap a portion to be a channel region of the oxide semiconductor film with the gate insulative film interposed therebetween;

(D) patterning the gate insulative film using the first mask or using the gate electrode as a mask, thereby forming the gate insulating layer; and

(E) thinning the oxide semiconductor film partially using the first mask or using the gate electrode as a mask, thereby forming an oxide semiconductor layer such that the portion to be the channel region of the oxide semiconductor layer has a greater thickness than portions at both sides of the portion to be the channel region.

[Item 16]

The method of Item 15, wherein a thickness of the thinned portion of the oxide semiconductor film is not less than ¼ and not more than ½ of a thickness of the portion to be the channel region.

[Item 17]

The method of Item 15 or 16, wherein the patterning of the gate insulative film in step (D) and the thinning of the oxide semiconductor film in step (E) are carried out in the same etching step.

[Item 18]

The method of Item 15 or 16, wherein the patterning of the gate insulative film in step (D) is realized by a first etching, and the thinning of the oxide semiconductor film in step (E) is realized by a second etching under a different condition from that of the first etching.

[Item 19]

The method of any of Items 15 to 18 wherein, after step (E), a resistance reduction treatment is performed such that specific resistance of an upper surface of the thinned portion of the oxide semiconductor layer is lower than specific resistance of the portion to be the channel region.

[Item 20]

The method of Item 19, wherein the resistance reduction treatment is performed such that specific resistance of a lateral surface of a non-thinned portion of the oxide semiconductor layer is also lower than the specific resistance of the portion to be the channel region.

[Item 21]

The method of Item 20, wherein the resistance reduction treatment includes

forming a metal film so as to cover the oxide semiconductor layer, the gate insulating layer and the gate electrode and so as to be in contact with a part of the surface of the oxide semiconductor layer which is exposed out of the gate insulating layer, the metal film containing a first metal element, and

oxidizing the metal film, thereby forming an insulative film which contains an oxide of the first metal element.

[Item 22]

The method of Item 21, wherein the first metal element is Al, and the insulative film is an alumina film.

[Item 23]

The method of any of Items 15 to 22, wherein

the gate insulating film is a silicon oxide film,

the electrically-conductive gate film includes a first metal film which is in contact with the gate insulating film, the first metal film containing Mg or La,

the method further includes (F), after step (A), diffusing part of Mg or La contained in the electrically-conductive gate film or the gate electrode into the gate insulating film or the gate insulating layer.

[Item 24]

The method of any of Items 15 to 23, wherein the oxide semiconductor film contains In, Ga and Zn.

According to an embodiment of the present invention, an oxide semiconductor TFT which is capable of improving the channel mobility and a manufacturing method thereof, and a display apparatus which includes the oxide semiconductor TFT are provided.

### BRIEF DESCRIPTION OF THE DRAWINGS

FIG. 1A is a schematic cross-sectional view of a TFT 101 of the first embodiment.

FIG. 1B is a schematic plan view of the TFT 101 of the first embodiment.

FIG. 1C is a cross-sectional view of another TFT 101a of the first embodiment.

FIG. 2 is a cross-sectional view of another TFT 102 of the first embodiment.

FIG. 3A is a stepwise cross-sectional view for illustrating a manufacturing method of the TFT 101.

FIG. 3B is a stepwise cross-sectional view for illustrating the manufacturing method of the TFT 101.

FIG. 3C is a stepwise cross-sectional view for illustrating the manufacturing method of the TFT 101.

FIG. 3D is a stepwise cross-sectional view for illustrating the manufacturing method of the TFT 101.

FIG. 4 is a cross-sectional view of a variation TFT 103.

FIG. 5 is a cross-sectional view of another variation TFT 104.

FIG. 6A is a stepwise cross-sectional view for illustrating a manufacturing method of the TFT 103.

FIG. 6B is a stepwise cross-sectional view for illustrating the manufacturing method of the TFT 103.

FIG. 6C is a stepwise cross-sectional view for illustrating the manufacturing method of the TFT 103.

FIG. 6D is a stepwise cross-sectional view for illustrating the manufacturing method of the TFT 103.

FIG. 7 is a cross-sectional view of a TFT 105 of the second embodiment.

FIG. 8 is a cross-sectional view of another TFT 106 of the second embodiment.

### DETAILED DESCRIPTION

### First Embodiment

Hereinafter, a thin film transistor (TFT) of the first embodiment of the present invention is described with reference to the drawings. The TFT of the present embodiment is an oxide semiconductor TFT which has a top gate configuration.

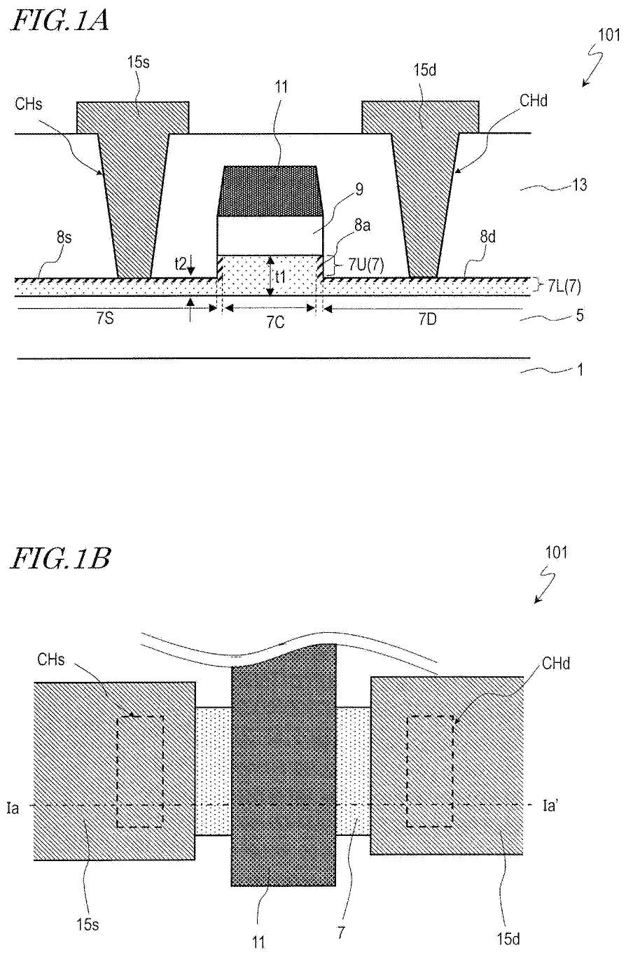

FIG. 1A and FIG. 1B are respectively a cross-sectional view and a plan view illustrating the TFT 101 of the present embodiment. FIG. 1A shows a cross section taken along line Ia-Ia′ of FIG. 1B.

The TFT 101 includes a substrate 1 such as glass substrate, an oxide semiconductor layer 7 supported by the substrate 1, a gate electrode 11 provided on part of the oxide semiconductor layer 7 with a gate insulating layer 9 interposed therebetween, and a source electrode 15s and a drain electrode 15d which are electrically coupled with the oxide semiconductor layer 7. Between the oxide semiconductor layer 7 and the substrate 1, a lower insulating layer 5 may be provided as an underlayer.

When viewed in the normal direction of the substrate 1, the oxide semiconductor layer 7 includes a first region 7S, a second region 7D, and a region 7C located between the first region 7S and the second region 7D in which the channel of the TFT 101 is to be formed (channel region). When viewed in the normal direction of the substrate 1, the gate electrode 11 overlaps the channel region 7C but overlaps none of the first region 7S and the second region 7D.

The channel region 7C of the oxide semiconductor layer 7 has a greater thickness than the first region 7S and the second region 7D. In the present embodiment, the oxide semiconductor layer 7 includes a lower layer 7L and an upper layer 7U provided on part of the lower layer 7L. The channel region 7C includes the upper layer 7U and the lower layer 7L. Each of the first region 7S and the second region 7D includes the lower layer 7L but does not include the upper layer 7U. In this specification, such a structure of the oxide semiconductor layer 7 is referred to as “recessed structure”. The oxide semiconductor layer 7 that has a recessed structure may be formed by reducing the thickness of the oxide semiconductor film at both sides of a portion which is to be the channel region (in other words, by forming recesses at both sides of a portion which is to be the channel region). Note that, in this example, the upper layer 7U and the lower layer 7L have the same composition, although they may have different compositions.

At least part of the lateral surfaces of the upper layer 7U (part of the lateral surfaces of the upper layer 7U which forms the step between the upper layer 7U and the lower layer 7L of the oxide semiconductor layer 7) may be aligned with the lateral surfaces of the gate insulating layer 9 in the thickness direction. This structure can be realized by performing patterning of the gate insulating layer 9 and thinning (thickness reduction) of the oxide semiconductor layer 7 (recess formation) using the same mask.

Since the oxide semiconductor layer 7 of the present embodiment has the above-described recessed structure, the channel of the TFT 101 is formed at a position deeper than the interface between the gate insulating layer 9 and the oxide semiconductor layer 7, i.e., than the upper surface of the upper layer 7U (buried channel). Therefore, deterioration of the channel mobility which is attributed to contamination with impurities from the gate insulating layer 9 can be suppressed as compared with a case where the channel is formed at the interface with the gate insulating layer 9 (surface channel). Thus, the channel mobility can be improved.

When the recessed structure is formed in the oxide semiconductor layer 7, the distance between the gate electrode 11 and the first region 7S and the second region 7D of the oxide semiconductor layer 7 increases. Therefore, there is a merit that the parasitic capacitance (fringe capacitance) between the lateral surfaces of the gate electrode 11 and the first region 7S and the second region 7D can be reduced.

In conventional top gate TFTs, if the overlap length of the gate and the source/drain is reduced for the purpose of reducing the parasitic capacitance, the channel mobility decreases so that it is difficult to achieve both high channel mobility and low parasitic capacitance. In contrast, in the present embodiment, the oxide semiconductor layer 7 has the recessed structure so that the channel mobility of the TFT 101 can be improved and the parasitic capacitance (fringe capacitance) can be reduced.

For example, in a current-driven display apparatus, if a pixel circuit TFT has large parasitic capacitance, switching of the pixel circuit TFT from ON to OFF causes accumulated charge which is present in the parasitic capacitance to be supplied to a light emitting device which is to be turned off. As a result, the lighting operation of the light emitting device which is to be turned off continues for a while, and there is a probability that display failure called “ghosting” will occur. In contrast, in the TFT 101 of the present embodiment, occurrence of ghosting can be suppressed because the parasitic capacitance (fringe capacitance) is reduced.

Although the channel mobility improves due to the buried channel structure (the on-current increases), there is a probability that the off-leak current will increase. However, oxide semiconductor TFTs usually have better off-leak characteristics than, for example, polysilicon TFTs and are therefore supposed to meet required TFT characteristics even if the off-leak current increases.

The thickness t2 of the first region 7S and the second region 7D of the oxide semiconductor layer 7 is not particularly limited but may be not less than ¼ and not more than ½ of the thickness t1 of the channel region 7C. When the thickness t2 is not less than ¼ of the thickness t1, electrical connection with the source electrode 15s and the drain electrode 15d can be more surely secured. When the thickness t2 is not more than ½ of the thickness t1, the channel mobility can be improved more effectively, and the fringe capacitance can be reduced. The thickness t1 of the channel region 7C may be, for example, not less than 30 nm and not more than 100 nm. The thickness t2 of the first region 7S and the second region 7D may be, for example, not less than 7.5 nm and not more than 15 nm.

At the surfaces of the first region 7S and the second region 7D of the oxide semiconductor layer 7, the oxide semiconductor layer 7 may have a first low-resistance region 8s and a second low-resistance region 8d, respectively, which have lower specific resistance than the channel region 7C. The source electrode 15s may be electrically coupled with the first low-resistance region 8s, and the drain electrode 15d may be electrically coupled with the second low-resistance region 8d.

As illustrated in the drawings, at the lateral surfaces of the upper layer 7U, the oxide semiconductor layer 7 may also have third low-resistance regions 8a which have lower specific resistance than the channel region 7C. Since the third low-resistance regions 8a are provided at the lateral surfaces of the upper layer 7U in addition to the upper surfaces of the first region 7S and the second region 7D, the on-resistance of the TFT 101 can be reduced more effectively. In this specification, the low-resistance regions provided at the surfaces of the oxide semiconductor layer 7 (including the first low-resistance region 8s, the second low-resistance region 8d and the third low-resistance regions 8a) are also generically and simply referred to as “low-resistance regions”. When the third low-resistance regions 8a are provided at the lateral surfaces of the upper layer 7U, a region of the oxide semiconductor layer 7 which overlaps the gate electrode 11 as viewed in the normal direction of the substrate 1 and whose resistance is not reduced is the “channel region 7C”.

The low-resistance regions may be formed by, for example, a resistance reduction treatment with the use of a metal film as will be described later. In this case, the first low-resistance region 8s, the second low-resistance region 8d and the third low-resistance regions 8a of the oxide semiconductor layer 7 are supplied (doped) with a metal element (Al) contained in the metal film used in the resistance reduction treatment. The aforementioned metal element may not be added to a region of the oxide semiconductor layer 7 whose resistance is not reduced (in this example, the channel region 7C and part of the lower layer 7L which is present at a level lower than the first low-resistance region Bs or the second low-resistance region 8d). The channel region 7C may not contain the aforementioned metal element or may contain a very small amount of the aforementioned metal element (at a lower density than in the low-resistance regions). As illustrated in FIG. 1C, an insulative film 18 which contains an oxide of the aforementioned metal element (e.g., Al₂O₃ (alumina) thin film) is provided over the first low-resistance region 8, the second low-resistance region 8d and the third low-resistance regions 8a so as to be in contact with these low-resistance regions. The insulative film 18 may cover the oxide semiconductor layer 7, the gate insulating layer 9 and the gate electrode 11.

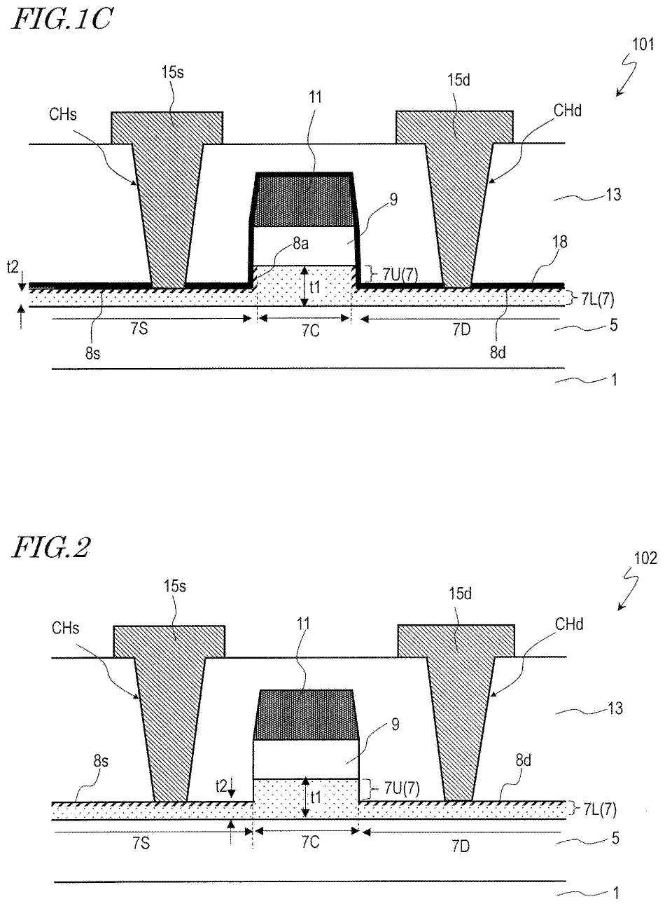

Alternatively, as illustrated in FIG. 2, the low-resistance regions are provided at the surfaces of the first region 7S and the second region 7D and may not be provided at the lateral surfaces of the upper layer 7U. For example, in the case where a resistance reduction treatment on exposed surfaces of the oxide semiconductor layer 7 is performed by a plasma treatment or the like, low-resistance regions 8s, 8d are formed at the surfaces of the first region 7S and the second region 7D but are unlikely to be formed at the lateral surfaces of the upper layer 7U.

The gate insulating layer 9 may be provided only between the oxide semiconductor layer 7 and the gate electrode 11. The gate insulating layer 9 and the gate electrode 11 may be, for example, patterned using the same mask.

An upper insulating layer 13 may be formed so as to cover the oxide semiconductor layer 7, the gate insulating layer 9 and the gate electrode 11. The upper insulating layer 13 has a first opening CHs which reaches the first region 7S and a second opening CHd which reaches the second region 7D. When the insulative film 18 is provided, the upper insulating layer 13 is provided on the insulative film 18, and the first opening CHs and the second opening CHd are provided in the upper insulating layer 13 and the insulative film 18 (FIG. 1C). The source electrode 15s is provided on the upper insulating layer 13 and in the first opening CHs. The source electrode 15s is electrically coupled with the first region 7S of the oxide semiconductor layer 7 (herein, the first low-resistance region 8) in the first opening CHs. The drain electrode 15d is provided on the upper insulating layer 13 and in the second opening CHd. The drain electrode 15d is electrically coupled with the second region 7D of the oxide semiconductor layer 7 (herein, the second low-resistance region 8d) in the second opening CHd.

In the TFT 101, the gate electrode 11, the source electrode 15s and the drain electrode 15d are preferably arranged such that the gate electrode 11 overlaps none of the source electrode 15s and the drain electrode 15d when viewed in the normal direction of the substrate 1. It is also preferred that the overlap length of the gate electrode 11 with the source electrode 15s and the drain electrode 15d is suppressed to a small length. Thereby, the parasitic capacitance between the gate electrode 11 and the source electrode 15s and the drain electrode 15d can be reduced.

Although not shown, a light shielding layer may be further provided on the substrate 1 side of the oxide semiconductor layer 7 (channel region 7C). Note that, however, in the case of a display apparatus which does not need a backlight, such as micro LED display apparatus, the light shielding layer may not be provided. Alternatively, another gate electrode (lower gate electrode) may be provided on the substrate 1 side of the oxide semiconductor layer 7 with another gate insulating layer interposed therebetween (double gate structure). The lower gate electrode may be connected with the gate electrode 11 or may be connected with a fixed potential. When the lower gate electrode is connected with a fixed potential, the on-current saturates due to the parasitic bipolar effects and, therefore, the effect of the present embodiment (the effect of increasing the on-current) can decrease in some cases. From the viewpoint of reducing the parasitic capacitance, it is preferred that the light shielding layer or the lower gate electrode is not provided.

The oxide semiconductor contained in the oxide semiconductor layer 7 is not particularly limited. Examples of the oxide semiconductor which can be used herein include binary oxides such as In—Zn based oxides and In—Ga based oxides, ternary oxides such as In—Ga—Zn based oxides and In—Sn—Zn based oxides, and quaternary metal oxides such as In—Sn—Ga—Zn based oxides. The oxide semiconductor may be amorphous or may be crystalline. The crystalline oxide semiconductor may be, for example, a polycrystalline oxide semiconductor, a microcrystalline oxide semiconductor, or a crystalline oxide semiconductor in which the c-axis is oriented generally perpendicular to the layer surface. The materials, compositions, structures and film formation methods of the amorphous or crystalline oxide semiconductor are disclosed in, for example, Japanese Patent No. 6275294. The disclosure of Japanese Patent No. 6275294 is incorporated herein by reference in its entirety.

<Manufacturing Method of TFT 101>

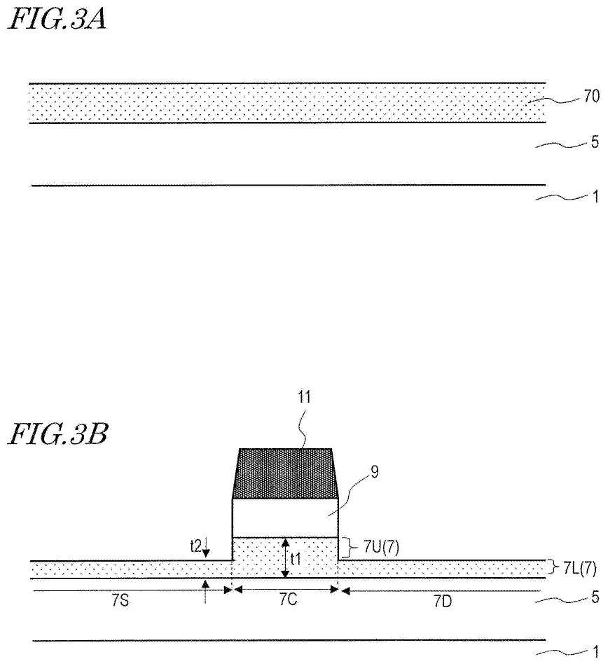

An example of the manufacturing method of the TFT 101 is described with reference to FIG. 3A to FIG. 3D.

Step 1: Forming Lower Insulating Layer and Oxide Semiconductor Film

First, as shown in FIG. 3A, a lower insulating layer 5 and an oxide semiconductor film 70 are formed in this order on the substrate 1.

As the substrate 1, for example, a substrate which has an insulative surface, such as glass substrate, silicon substrate, thermostable plastic substrate (resin substrate), etc., can be used.

As the lower insulating layer 5, a silicon oxide (SiO₂) layer, a silicon nitride (SiNx) layer, a silicon oxynitride (SiOxNy; x>y) layer, a silicon nitroxide (SiNxOy; x>y) layer, or the like, can be appropriately used. The lower insulating layer 5 may have a multilayer structure. Herein, as the lower insulating layer 5, for example, a multilayer film is formed by CVD which includes a silicon nitride (SiNx) layer as the lower layer and a silicon oxide (SiO₂) layer as the upper layer. When an oxide film, such as silicon oxide film, is used as the lower insulating layer 5 (if the lower insulating layer 5 has a multilayer structure, as the uppermost layer of the multilayer structure), oxidation deficiencies in the channel region 7C of the oxide semiconductor layer 7 that is formed in a subsequent step can be reduced by the oxide film and, therefore, decrease in resistance of the channel region 7C can be suppressed. The thickness of the lower insulating layer 5 is not particularly limited but may be, for example, not less than 250 nm and not more than 400 nm.

The oxide semiconductor film 70 is formed on the lower insulating layer 5 by, for example, sputtering. Herein, as the oxide semiconductor film 70, a film is formed which contains an In—Ga—Zn—O based semiconductor (In:Ga:Zn=1:1:1) as a major constituent. As the sputtering gas (atmosphere), a mixture gas of an inert gas such as argon gas and an oxidizing gas such as O₂, CO₂, O₃, H₂O, N₂O, or the like. The formation conditions, such as the sputtering target used, the mixture ratio of the sputtering gas (the proportion of the oxygen gas to the inert gas), etc., can be appropriately selected according to the composition (or composition ratio) of the oxide semiconductor film 70 to be formed. The thickness of the oxide semiconductor film 70 may be, for example, not less than 30 nm and not more than 100 nm.

Thereafter, a heat treatment on the oxide semiconductor film 70 (first heat treatment) may be performed. Herein, the heat treatment is carried out in the environmental atmosphere at a temperature equal to or higher than 300° C. and equal to or lower than 500° C. The duration of the first heat treatment is, for example, not less than 30 minutes and not more than 2 hours. By this heat treatment, the oxygen deficiencies in the channel region 7C can be reduced, so that desired TFT characteristics can be achieved. Before or after the first heat treatment, the oxide semiconductor film 70 may be patterned so as to have a predetermined shape (e.g., island shape).

Step 2: Forming Gate Insulating Layer and Gate Electrode and Forming Oxide Semiconductor Layer

Then, as shown in FIG. 3B, a gate insulating layer 9 and a gate electrode 11 are formed on part of the oxide semiconductor film 70.

First, a gate insulative film, which is to be the gate insulating layer, and an electrically-conductive gate film, which is to be the gate electrode, are formed in this order so as to cover the oxide semiconductor layer 7. The thickness of the gate insulative film is not particularly limited but may be, for example, not less than 100 nm and not more than 200 nm, or not less than 300 nm and not more than 400 nm. The thickness of the electrically-conductive gate film is not particularly limited but may be, for example, not less than 300 nm and not more than 400 nm.

The gate insulative film can be formed by, for example, CVD. As the insulative film, a silicon oxide (SiO₂) film, a silicon nitride (SiNx) film, a silicon oxynitride (SiOxNy; x>y) film, a silicon nitroxide (SiNyOx; y>x) film, or a multilayer film thereof can be appropriately used. When an oxide film such as silicon oxide film is used as the insulative film (if a multilayer film is used, as the lowermost film of the multilayer film), oxidation deficiencies in the channel region 7C of the oxide semiconductor layer 7 can be reduced and, therefore, decrease in resistance of the channel region 7C can be suppressed.

The electrically-conductive gate film can be formed by, for example, sputtering. As the material of the electrically-conductive gate film, for example, a single metal such as molybdenum (Mo), tungsten (W), copper (Cu), chromium (Cr), tantalum (Ta), aluminum (Al), titanium (Ti), etc., a material prepared by adding nitrogen, oxygen, or another metal to the single metal, or a transparent electrically-conductive material such as indium tin oxide (ITO) can be used.

Subsequently, a first resist mask (not shown) is formed on part of the electrically-conductive gate film. Thereafter, patterning of the electrically-conductive gate film is performed using the first resist mask, whereby a gate electrode 11 is formed. The patterning of the electrically-conductive gate film can be realized by wet etching or dry etching.

Then, patterning of the gate insulative film and patterning of the oxide semiconductor film 70 (thinning) are performed by, for example, dry etching using the first resist mask. Alternatively, after the first resist mask is removed, patterning of the gate insulative film and thinning of the oxide semiconductor film 70 may be performed using the patterned gate electrode 11 as a mask. The patterning of the gate insulative film and the thinning of the oxide semiconductor film 70 can be carried out through the same etching process (for example, under the same conditions with the use of the same etching gas). Thereby, the gate insulating layer 9 results from the gate insulative film, and upper portions of parts of the oxide semiconductor film 70 not overlapping the gate electrode 11 (parts which are to be the first region 7S and the second region 7D) are removed, resulting in the oxide semiconductor layer 7 which has a recessed structure. A portion of the oxide semiconductor layer 7 which overlaps the gate electrode 11 as viewed in the normal direction of the substrate 1 and which is not thinned in this step forms the channel region 7C. Portions of the oxide semiconductor layer 7 at both sides of the channel region 7C which are etched (thinned) form the first region 7S and the second region 7D, respectively.

The etching conditions for the dry etching, such as etching gas type, flow rate, etching duration, etc., can be adjusted such that, for example, the gate insulative film and the oxide semiconductor film 70 are concurrently etched (the etching selection ratio is low) and that the thickness t2 of the thinned portions of the oxide semiconductor film 70 (the first region 7S and the second region 7D) is not less than ¼ and not more than ½ of the thickness t1 of a non-thinned portion of the oxide semiconductor film 70 (the channel region 7C). When a silicon oxide (SiO₂) film is used as the gate insulative film, the etching may be carried out by, for example, inductively coupled plasma reactive ion etching (ICP-RIE) using a chlorine based gas, such as BCl₃/O₂ mixture gas, Cl₂ gas, etc., as the etching gas under the following conditions; pressure: 10 mT, BCl₃ flow rate: 1000 sccm, O₂ flow rate: 800 sccm, RF power (upper portion): 30000 W/RF power (lower portion): 30000 W.

Alternatively, the etching of the gate insulative film and the thinning of the oxide semiconductor film 70 may be carried out under different conditions. When a silicon oxide (SiO₂) film is used as the gate insulative film, the etching of the gate insulative film may be carried out using, for example, CF₄/O₂ (or H₂) as the etching gas under the following conditions; CF₄ flow rate: 7000 sccm, O₂ flow rate: 1000 sccm, pressure: 50 mTorr, RF power (upper portion): 10000 W/RF power (lower portion): 20000 W. Thereafter, the thinning of the oxide semiconductor film 70 may be carried out using a CH₄/H₂ mixture gas as the etching gas under the following conditions; CH₄ flow rate: 5000 sccm, H2 flow rate: 1000 sccm, pressure: 50 mTorr, RF power (upper portion): 10000 W.

In this step, lateral surfaces of the gate insulating layer 9, lateral surfaces of the gate electrode 11, and at least part of lateral surfaces (stepped portion) of the upper layer 7U of the oxide semiconductor layer 7 can be aligned in the thickness direction. That is, when viewed in the normal direction of the substrate 1, the periphery of the gate insulating layer 9, the periphery of the gate electrode 11, and at least part of the periphery of the upper layer 7U of the oxide semiconductor layer 7 can be aligned with one another.

Step 3: Resistance Reduction Treatment

Then, as shown in FIG. 3C, a resistance reduction treatment is performed on the exposed surfaces of the oxide semiconductor layer 7 so as to have lower specific resistance than a portion which overlaps the gate electrode 11 when viewed in the normal direction of the substrate 1.

Specifically, first, a metal film (e.g., Al film (thickness: 5 nm)) is formed so as to cover the oxide semiconductor layer 7, the gate insulating layer 9 and the gate electrode 11. The metal film is arranged so as to be in contact with the exposed surfaces of the oxide semiconductor layer 7. Although the method for forming the metal film is not particularly limited, for example, sputtering or the like can be used. Then, for example, annealing is performed in an atmosphere which contains oxygen, whereby the metal film is oxidized. Herein, annealing is performed on the Al film for one hour in the air at the temperature of 200° C.

By the above-described resistance reduction treatment, the entire exposed surfaces of the oxide semiconductor layer 7 (including the upper surfaces of the first region 7S and the second region 7D and the lateral surfaces of the upper layer 7U) are doped with a metal element contained in the metal film (e.g., Al), whereby low-resistance regions 8, 8d, 8a are formed. The low-resistance regions 8s, 8d, 8a are, for example, In—Ga—Zn—O based oxide regions doped with Al. On the low-resistance regions 8s, 8d, 8a, an insulative film 18 which contains an oxide of the aforementioned metal element (e.g., Al₂O₃ (alumina) film) is formed.

Alternatively, by using an insulative film which can deoxidize the oxide semiconductor such as a nitride film (e.g., silicon nitride film) as the upper insulating layer 13, the resistance of regions of the oxide semiconductor layer 7 which are in contact with the nitride film (the upper surfaces of the first region 7S and the second region 7D and the lateral surfaces of the upper layer 7U) can be reduced to a level lower than the resistance of a region of the oxide semiconductor layer 7 which is in contact with the oxide film (the upper surface of the channel region 7C). In this case, as illustrated in FIG. 1A, the insulative film 18 is not formed, and the low-resistance regions 8s, 8d, 8a are in contact with the upper insulating layer 13.

Alternatively, a plasma treatment may be performed as the resistance reduction treatment. Examples of the plasma treatment include argon plasma treatment, ammonium plasma treatment and hydrogen plasma treatment. Alternatively, nitrogen, phosphorus, or the like, may be added to the oxide semiconductor layer 7 by ion implantation using the gate electrode 11 as a mask. When these treatments are employed, the low-resistance regions 8s, 8d are formed at the surfaces of the first region 7S and the second region 7D as illustrated in FIG. 2, although low-resistance regions are not formed at the lateral surfaces of the upper layer 7U in some cases.

Step 4: Forming Upper Insulating Layer

Then, as shown in FIG. 3D, an upper insulating layer 13 is formed so as to cover the gate electrode 11, the gate insulating layer 9 and the oxide semiconductor layer 7. When the insulative film 18 is provided, the upper insulating layer 13 is located on the insulative film 18.

The upper insulating layer 13 can be formed by a single inorganic insulating layer of a silicon oxide film, a silicon nitride film, a silicon oxynitride film or a silicon nitroxide film, or a multilayer film thereof. As previously described, as the upper insulating layer 13 (if the upper insulating layer 13 has a multilayer structure, as the lowermost layer of the multilayer structure), an insulative film which can deoxidize the oxide semiconductor, such as a silicon nitride film, may be used. Herein, as the upper insulating layer 13, for example, a silicon oxide layer is deposited by CVD and, thereafter, a silicon oxide film is formed by coating. The thickness of the upper insulating layer 13 (or the thickness of the lowermost layer of the upper insulating layer 13) is not particularly limited but may be, for example, not less than 100 nm and not more than 500 nm.

Thereafter, a first opening CHs and a second opening CHd are formed in the upper insulating layer 13 (and the insulative film 18) by, for example, dry etching such that the first opening CHs reaches the surface of the first region 7S (the first low-resistance region 8s) and the second opening CHd reaches the surface of the second region 7D (the second low-resistance region 8d).

Step 5: Forming Source and Drain Electrodes

Then, an electrically-conductive source film is formed on the upper insulating layer 13 and in the first opening CHs and the second opening CHd, and the formed electrically-conductive source film is patterned. Thereby, a source electrode 15s and a drain electrode 15d are formed from the electrically-conductive source film.

The material of the electrically-conductive source film can be the same as the material of the above-described electrically-conductive gate film. The thickness of the electrically-conductive source film is not particularly limited but may be, for example, not less than 300 nm and not more than 400 nm. The patterning of the electrically-conductive source film can be realized by dry etching or wet etching. In this way, the TFT 101 is manufactured.

(Variation)

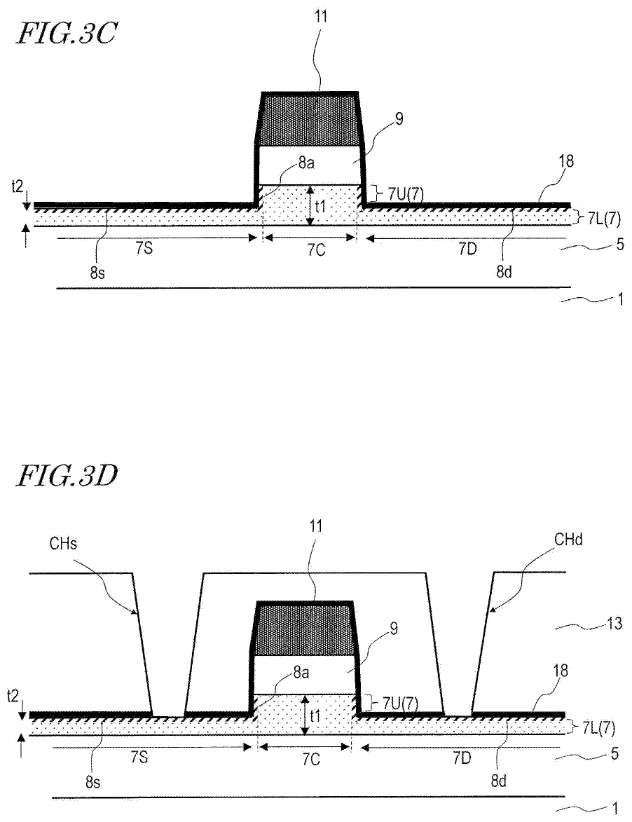

FIG. 4 is a cross-sectional view showing another TFT 103 of the present embodiment.

The TFT 103 is different from the TFT 101 in that a silicon oxide (SiO₂) layer which contains a metal element (hereinafter, “second metal element”), hereinafter referred to as “metal-containing gate insulating layer 9m”, is used as the gate insulating layer. The second metal element is Mg or La. The metal-containing gate insulating layer 9m may contain both Mg and La.

Since the metal-containing gate insulating layer 9m contains Mg or La, the metal-containing gate insulating layer 9m can have higher relative permittivity than the relative permittivity of silicon oxide (SiO₂) (e.g., 3.9). The thickness of the metal-containing gate insulating layer 9m may be, for example, not less than 100 nm and not more than 200 nm.

Since the TFT 103 includes the metal-containing gate insulating layer 9m that is a SiO₂ layer to which Mg or La is added, the TFT 103 can realize higher channel mobility than a TFT in which the gate insulating layer is made of only SiO₂. This is estimated to be attributed to formation of an electrical interface dipole by Mg or La at the interface between the metal-containing gate insulating layer 9m and the gate electrode 11 and reduction of the interface trap density due to the interface dipole. The above-described effect achieved by addition of Mg or La to the SiO₂ layer is knowledge attained after continuous research by the present inventors.

Further, in the TFT 103, even if the second metal element is diffused to the vicinity of the interface between the oxide semiconductor layer 7 and the metal-containing gate insulating layer 9m, the influence of the second metal element on the channel can be reduced more effectively because the channel is formed at a position deeper than the interface between the oxide semiconductor layer 7 and the metal-containing gate insulating layer 9m (buried channel structure).

The gate electrode 11 may include a first metal layer 11L which contains the second metal element. The first metal layer 11L may be in direct contact with the metal-containing gate insulating layer 9m. In this example, the gate electrode 11 has a multilayer structure which includes a first metal layer 11L and a second metal layer 11U provided on the first metal layer 11L. The gate electrode 11 may have a single layer structure of the first metal layer 11L. When the gate electrode 11 includes the first metal layer 11L, as will be described later, the second metal element is diffused from the first metal layer 11L into the silicon oxide layer, whereby a metal-containing gate insulating layer 9m containing the second metal element can be formed.

The first metal layer 11L may be, for example, a Cu alloy (e.g., CuMgAl alloy, CuLa alloy) layer which contains the second metal element. The second metal layer 11U may be, for example, a Cu layer. Such a metal element (referred to as “common metal element”; herein, Cu) commonly contained as a major constituent in the first metal layer 11L and the second metal layer 11U brings about such a merit that these metal layers can be simultaneously patterned using a predetermined etchant. In an alloy which “contains the common metal element as a major constituent”, for example, the proportion of an added metal element other than the common metal element (if a plurality of added metal elements are contained, the total proportion of the added metal elements) may be, for example, more than 0 at % and not more than 20 at %.

The first metal layer 11L is not limited to a Cu alloy layer but may be an Al alloy (e.g., AlNiCuLa alloy) layer.

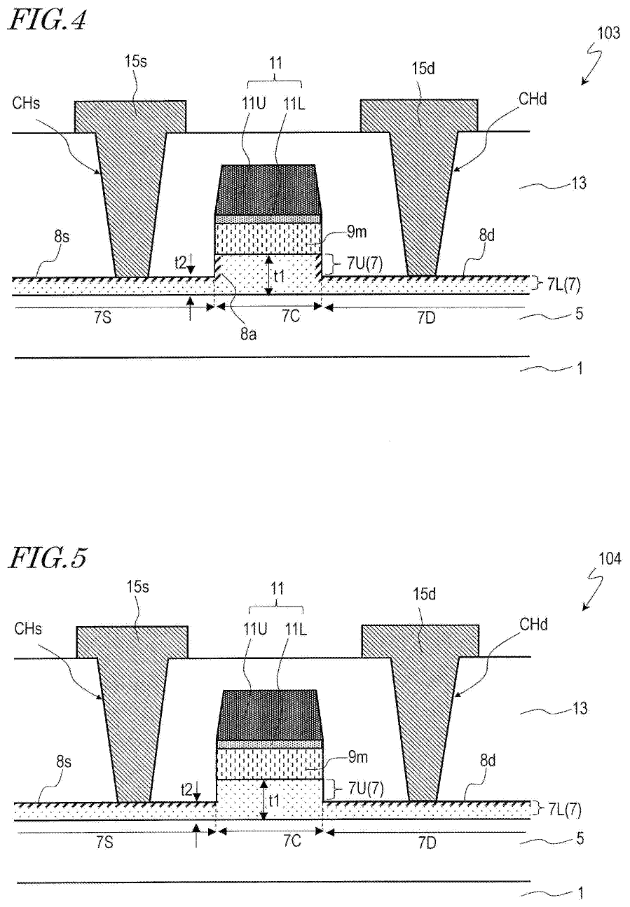

Also in this variation, as illustrated in FIG. 5, a low-resistance region may not be formed at the lateral surfaces of the upper layer 7U of the oxide semiconductor layer 7. The TFT 104 shown in FIG. 5 can be formed by the same resistance reduction treatment as that performed on the TFT 102.

<Manufacturing Method of TFT 103>

The TFT 103 can be manufactured by the same method as that for the TFT 101. However, the manufacturing method of the TFT 103 is different from the manufacturing method of the TFT 101 in that, in STEP 2, an electrically-conductive gate film is formed which includes a metal film which contains the second metal element, and the method further includes the step of diffusing the second metal element from the electrically-conductive gate film into the gate insulative film before patterning of the electrically-conductive gate film. Hereinafter, only the steps which are different from the manufacturing method of the TFT 101 are described.

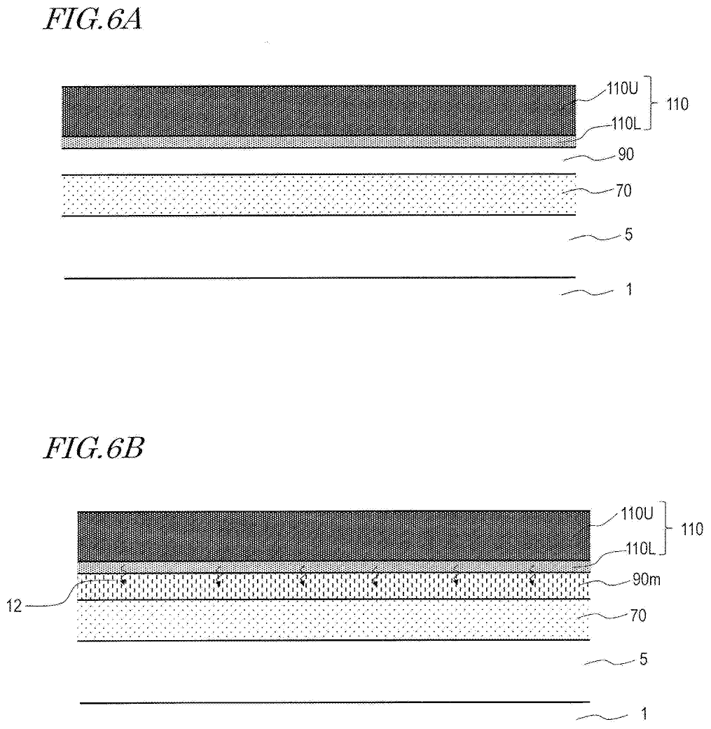

After the oxide semiconductor film 70 is formed on the substrate 1 in the same way as in the manufacturing method of the TFT 101, a gate insulative film 90 and an electrically-conductive gate film 110 are formed in this order on the oxide semiconductor film 70 as shown in FIG. 6A.

As the gate insulative film 90, a silicon oxide (SiO₂) film is formed by, for example, CVD.

As the electrically-conductive gate film 110, for example, a multilayer film is formed in which a first metal film 110L that contains the second metal element and a second metal film 110U that does not contain the second metal element are stacked up in this order. The first metal film 110L and the second metal film 110U may contain a common metal element as a major constituent. The second metal film 110U may have lower specific resistance than the first metal film 110L. The total thickness of the electrically-conductive gate film 110 may be, for example, not less than 200 nm and not more than 600 nm.

Herein, a CuMgAl alloy film (Mg: for example, 0-10 at %, Al: for example, 0-10 at %) is formed as the first metal film 110L by, for example, sputtering, and a Cu film is formed as the second metal film 110U.

Then, as shown in FIG. 6B, the second metal element is diffused from the first metal film 110L into the gate insulative film 90. Herein, a heat treatment is performed at the temperature of, for example, equal to or higher than 400° C. and equal to or lower than 450° C. (second heat treatment). Thereby, the second metal element is diffused into the gate insulative film 90, and a metal-containing gate insulative film 90m which contains the second metal element is formed.

Thereafter, as shown in FIG. 6C, patterning of the electrically-conductive gate film 110, the metal-containing gate insulative film 90m and the oxide semiconductor film 70 is performed. The patterning method may be the same as that previously described with reference to FIG. 3B. For example, by wet etching with the use of a hydrogen peroxide based etchant, the first metal film 110L and the second metal film 110U can be simultaneously patterned.

Then, as shown in FIG. 6D, a resistance reduction treatment on the oxide semiconductor layer 7 is performed, whereby low-resistance regions 8s, 8d, 8a are formed. The method of the resistance reduction treatment may be the same as that previously described with reference to FIG. 3C.

Although not shown, thereafter, the upper insulating layer 13 and the source electrode 15s and the drain electrode 15d are formed in the same way as for the TFT 101. In this way, the TFT 103 is manufactured.

The manufacturing method of the TFT 103 is not limited to the above-described example. For example, the first heat treatment for reducing the oxygen deficiencies in the oxide semiconductor film 70 may be concurrently carried out with the second heat treatment for diffusion of the second metal element after the electrically-conductive gate film 110 is formed. Alternatively, the second heat treatment for diffusion of the second metal element may be carried out after the patterning of the electrically-conductive gate film 110, the metal-containing gate insulative film 90m and the oxide semiconductor film 70.

The gate electrode 11 of this variation may not contain the second metal element. In this case, the metal-containing gate insulative film 90m that contains the second metal element may be formed on the oxide semiconductor film 70 by, for example, sputtering.

### Second Embodiment

Hereinafter, a thin film transistor (TFT) of the second embodiment of the present invention is described with reference to the drawings.

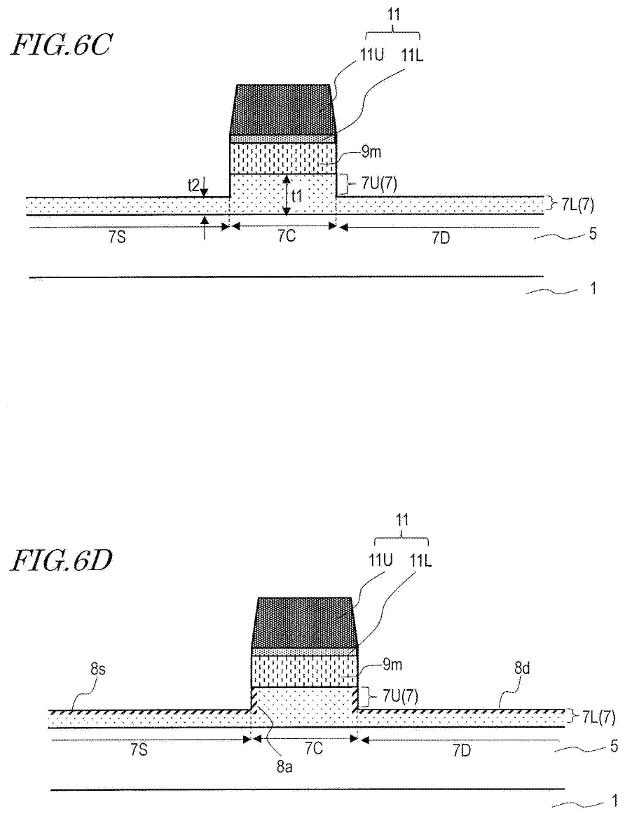

FIG. 7 is a cross-sectional view illustrating a TFT 105 of the present embodiment.

The TFT 105 is different from the TFTs 103, 104 shown in FIG. 4 and FIG. 5 in that the oxide semiconductor layer 7 does not have a recessed structure. Specifically, the TFT 105 includes a substrate 1, an oxide semiconductor layer 7 supported by the substrate 1, a gate electrode 11 provided on part of the oxide semiconductor layer 7 with the metal-containing gate insulating layer 9m interposed therebetween, and a source electrode 15s and a drain electrode 15d which are electrically coupled with the oxide semiconductor layer 7. In the oxide semiconductor layer 7, the thickness t1 of the channel region 7C (a portion overlapping the gate electrode 11) may be substantially equal to the thickness of the first region 7S and the second region 7D. The “substantially equal thickness” includes a case where, in patterning the metal-containing gate insulating layer 9m, the surface portion of the oxide semiconductor layer 7 is overetched. In such a case, the thickness of the first region 7S and the second region 7D is, for example, not more than 1/10 of the thickness t1 of the channel region 7C.

The metal-containing gate insulating layer 9m is a silicon oxide (SiO₂) layer which contains the second metal element. The second metal element is Mg or La. The structure, composition ratio, formation method, etc., of the metal-containing gate insulating layer 9m are the same as those of the TFT 103 shown in FIG. 4.

Also in the present embodiment, the metal-containing gate insulating layer 9m can have higher relative permittivity than the relative permittivity of SiO₂ (e.g., 3.9) as in the TFT 103. Using the metal-containing gate insulating layer 9m can realize higher channel mobility than a TFT in which the gate insulating layer is made of only SiO₂.

The gate electrode 11 may include the first metal layer 11L which contains the second metal element. The gate electrode 11 may have a multilayer structure which includes the first metal layer 11L and the second metal layer 11U as previously described in the variation or may have a single layer structure of the first metal layer 11L.

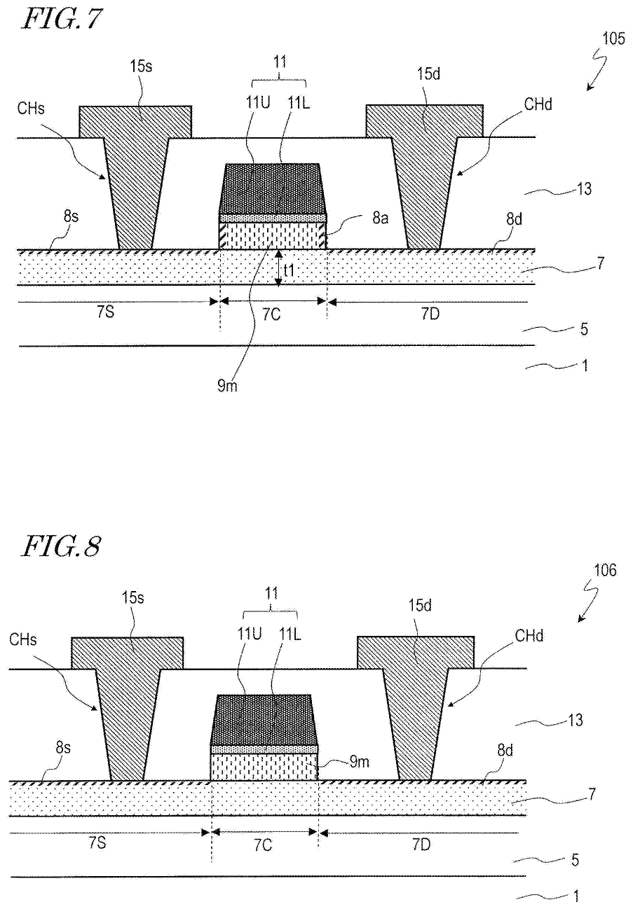

Also in the present embodiment, as illustrated in FIG. 8, a low-resistance region may not be formed at the lateral surfaces of the upper layer 7U of the oxide semiconductor layer 7.

<Manufacturing Method of TFT 105>

The TFT 105 can be manufactured by the same method as that for the TFTs 103, 104.

First, as previously described with reference to FIG. 6A and FIG. 6B, an oxide semiconductor film 70, a gate insulative film 90 and an electrically-conductive gate film 110 are formed, and then, the second metal element is diffused from the electrically-conductive gate film 110, whereby a metal-containing gate insulative film 90m is formed.

Thereafter, patterning of the electrically-conductive gate film 110 and the metal-containing gate insulative film 90m is performed, resulting in a gate electrode 11 and a gate insulating layer 9. Note that, however, in the patterning step for formation of the gate insulating layer 9, the etching is carried out under such conditions that the oxide semiconductor film 70 is unlikely to be etched away. Subsequent steps are the same as those for the TFT 103.

The step of diffusing the second metal element into the gate insulative film (or gate insulating layer) may be carried out after patterning of the gate electrode 11. Alternatively, the metal-containing gate insulative film 90m which contains the second metal element may be deposited by sputtering, or the like, without the diffusion step.

<Display Apparatus>

The thin film transistors of the present embodiment are applicable to, for example, circuit boards such as active matrix substrates, various display apparatuses such as liquid crystal display apparatuses, organic EL display apparatuses, and micro LED display apparatuses, image sensors, electronic devices, etc.

Hereinafter, an active matrix substrate and a display apparatus which include thin film transistors of the present embodiment are described.

The active matrix substrate has a display region which includes a plurality of pixels and pixel circuits which are arranged so as to correspond to respective ones of the plurality of pixels. Each of the pixel circuits includes at least one thin film transistor (pixel circuit TFT) as a circuit element. In a region of the active matrix substrate exclusive of the display region (peripheral region), peripheral circuits such as driving circuits are monolithically (integrally) provided in some cases. The peripheral circuit includes at least one thin film transistor (peripheral circuit TFT) as a circuit element. The thin film transistors of the present embodiment can be used as a pixel circuit TFT and/or a peripheral circuit TFT. Such an active matrix substrate can be used not only in a voltage-driven display apparatus, such as liquid crystal display apparatuses, but also in a current-driven display apparatus.

The thin film transistors of the present embodiment are suitably applicable to, particularly, current-driven display apparatuses. In a current-driven display apparatus such as organic EL display apparatus, micro LED display apparatuses, or the like, a plurality of current-driven light emitting devices (organic EL device, LED device, etc.) are arranged so as to correspond to respective pixels. Each pixel circuit (also referred to as “pixel driving circuit”) drives a corresponding one of the light emitting devices. The thin film transistors of the present embodiment can have high channel mobility (current drivability) and are therefore suitably applicable to pixel driving circuits which drive the current-driven light emitting devices, and accordingly can achieve still higher luminance. Configurations of the pixel driving circuit are disclosed in, for example, WO 2016/035413 and WO 2004/107303. The disclosures of these documents are incorporated herein by reference in their entireties.

This application is based on U.S. Provisional Patent Applications No. 62/852,765 filed on May 24, 2019, the entire contents of which are hereby incorporated by reference.

What is claimed is:

1. A thin film transistor comprising:
a substrate;
an oxide semiconductor layer supported by the substrate, the oxide semiconductor layer including a first region, a second region, and a channel region located between the first region and the second region;
a gate electrode provided on the channel region of the oxide semiconductor layer so as to overlap the channel region with a gate insulating layer interposed therebetween, the gate electrode overlapping the channel region of the oxide semiconductor layer but overlapping none of the first region and the second region when viewed in a normal direction of the substrate;
a source electrode electrically coupled with the first region of the oxide semiconductor layer; and
a drain electrode electrically coupled with the second region of the oxide semiconductor layer,
wherein the channel region of the oxide semiconductor layer has a greater thickness than the first region and the second region,
the oxide semiconductor layer includes a lower layer and an upper layer provided on part of the lower layer, and
the channel region includes the upper layer and the lower layer, and each of the first region and the second region includes the lower layer but does not include the upper layer.

2. The thin film transistor of claim 1, wherein a thickness of the first region and the second region is not less than ¼ and not more than ½ of a thickness of the channel region.

3. The thin film transistor of claim 1, wherein the oxide semiconductor layer includes a low-resistance region at an upper surface of the first region and the second region, the low-resistance region having lower specific resistance than the channel region.

4. The thin film transistor of claim 3, wherein the low-resistance region is also provided at a lateral surface of the upper layer of the oxide semiconductor layer.

5. The thin film transistor of claim 4, wherein
the low-resistance region contains a first metal element while the channel region does not contain the first metal element or contains the first metal element at a lower density than in the low-resistance region, and
an insulative film is provided on the low-resistance region so as to be in contact with the low-resistance region, the insulative film containing an oxide of the first metal element.

6. The thin film transistor of claim 5, wherein the first metal element is Al, and the insulative film is an alumina film.

7. The thin film transistor of claim 1, further comprising an upper insulating layer covering the oxide semiconductor layer, the gate insulating layer and the gate electrode, wherein
the source electrode is electrically coupled with the first region in a first opening provided in the upper insulating layer, and
the drain electrode is electrically coupled with the second region in a second opening provided in the upper insulating layer.

8. The thin film transistor of claim 1, wherein a lateral surface of the gate electrode, a lateral surface of the gate insulating layer, and at least part of a lateral surface of the oxide semiconductor layer are aligned with one another.

9. The thin film transistor of claim 1, wherein the oxide semiconductor layer contains In, Ga and Zn.

10. A display apparatus comprising:
the thin film transistor as set forth in claim 1;
a display region which has a plurality of pixels; and
a pixel circuit arranged so as to correspond to respective ones of the plurality of pixels,
wherein the pixel circuit includes the thin film transistor.

11. The display apparatus of claim 10, further comprising a current-driven light emitting device arranged so as to correspond to respective one of the plurality of pixels, wherein the pixel circuit drives the light emitting device.

12. A manufacturing method of a thin film transistor supported by a substrate, the method comprising:
(A) forming an oxide semiconductor film on the substrate;
(B) forming a gate insulative film and an electrically-conductive gate film in this order on the oxide semiconductor film;
(C) patterning the electrically-conductive gate film using a first mask, thereby forming a gate electrode so as to overlap a portion to be a channel region of the oxide semiconductor film with the gate insulative film interposed therebetween;
(D) patterning the gate insulative film using the first mask or using the gate electrode as a mask, thereby forming a gate insulating layer; and
(E) thinning the oxide semiconductor film partially using the first mask or using the gate electrode as a mask, thereby forming an oxide semiconductor layer such that the portion to be the channel region of the oxide semiconductor layer has a greater thickness than portions at both sides of the portion to be the channel region.

13. The method of claim 12, wherein a thickness of the thinned portion of the oxide semiconductor film is not less than ¼ and not more than ½ of a thickness of the portion to be the channel region.

14. The method of claim 12, wherein the patterning of the gate insulative film in step (D) and the thinning of the oxide semiconductor film in step (E) are carried out in the same etching step.

15. The method of claim 12, wherein the patterning of the gate insulative film in step (D) is realized by a first etching, and the thinning of the oxide semiconductor film in step (E) is realized by a second etching under a different condition from that of the first etching.

16. The method of claim 12 wherein, after step (E), a resistance reduction treatment is performed such that specific resistance of an upper surface of the thinned portion of the oxide semiconductor layer is lower than specific resistance of the portion to be the channel region.

17. The method of claim 16, wherein the resistance reduction treatment is performed such that specific resistance of a lateral surface of a non-thinned portion of the oxide semiconductor layer is also lower than the specific resistance of the portion to be the channel region.

18. The method of claim 17, wherein the resistance reduction treatment includes
forming a metal film so as to cover the oxide semiconductor layer, the gate insulating layer and the gate electrode and so as to be in contact with a part of the surface of the oxide semiconductor layer which is exposed out of the gate insulating layer, the metal film containing a first metal element, and
oxidizing the metal film, thereby forming an insulative film which contains an oxide of the first metal element.

19. The method of claim 18, wherein the first metal element is Al, and the insulative film is an alumina film.

20. The method of claim 12, wherein the oxide semiconductor film contains In, Ga and Zn.
